(19) United States
(12) Patent Application Publication
(10) Pub. No.: US 2008/0105940 A1
(43) Pub. Date: May 8, 2008

(54) SOI-based inverse nanotaper optical detector

(75) Inventors: David Piede, Allentown, PA (US); Vipulkumar Patel, Breinigsville, PA (US); Margaret Ghiron, Malvern, PA (US); Prakash Gothoskar, Allentown, PA (US); Robert Keith Montgomery, Easton, PA (US)

Correspondence Address: Wendy W. Koba, PO Box 556, Springtown, PA, 18081, US

(73) Assignee: SiOptical, Inc.

(21) Appl. No.: 11/811,799

(22) Filed: Jun. 12, 2007

Related U.S. Application Data
(60) Provisional application No. 60/813,936, filed on Jun. 15, 2006.

(51) Int. Cl. H01L 31/0232

(52) U.S. Cl. 257/432; 257/E31.127

(57) ABSTRACT

A photodetector integrated within a silicon-on-insulator (SOI) structure is formed directly upon an inverse nanotaper endface coupling region to reduce polarization sensitivity at the detector's input. The photodetector may be germanium-based PN (PIN) junction photodetector, a SiGe photodetector, a metal/silicon Schottky barrier photodetector, or any other suitable silicon-based photodetector. The inverse nanotaper photodetector may also be formed as an in-line monitoring device, converting only a portion of the in-coupled optical signal and allowing for the remainder to thereafter propagate along an associated optical waveguide.

### CROSS-REFERENCE TO RELATED APPLICATION

The present application claims the benefit of Provisional Application No. 60/813,936, filed Jun. 15, 2006.

### TECHNICAL FIELD

The present invention is related to a photodetector arrangement for use with silicon-based opto-electronic arrangements and, more particularly, to an SOI-based photodetector integrated with an inverse nanotaper input coupler.

### DESCRIPTION OF THE PRIOR ART

Conversion of photons to electrons is essential for the successful integration of microphotonics with microelectronics. InGaAs-based PIN photodetectors are commonly used for communication applications because of their high responsivity and speed. The majority of the InGaAs-based detectors are normal incidence detectors and, as a result, the integration of such devices on silicon surfaces is expensive and complicated. Additionally, integration of high-speed InGaAs detectors requires special optics to focus light into a small active area, which has been found to have a deleterious effect on device performance.

Germanium-based area detectors are also well known in the art. Germanium detectors exhibit a higher dark current than InGaAs-based detectors, which limit their application in the communication industry. In recent years, attempts have been made to improve the performance of polycrystalline germanium-based detectors for these applications. One exemplary prior art poly-germanium detector is discussed in an article entitled “Efficient high-speed near-infrared Ge photodetectors integrated on Si substrates”, by L. Colace et al., appearing in Applied Physics Letters, Vol. 76, p. 1231 et seq, 2000.

U.S. Pat. No. 6,897,498 issued to P. Gothoskar et al. on May 24, 2005 discloses an exemplary prior art photodetector structure for use with silicon-on-insulator (SOI)-based devices. The Gothoskar et al. reference describes a photodetector that is monolithically integrated with the relatively thin silicon surface layer (SOI layer) of the SOI structure. A poly-germanium layer is formed over a portion of the SOI layer, where the dimensions of the poly-germanium layer are used to control the amount of light that is absorbed. The bandgap of germanium (˜0.72 eV) allows for efficient absorption of near-IR wavelength light as an input optical signal propagates along an incoming SOI layer waveguide and encounters the overlying poly-germanium layer. The optical mode propagating in the silicon waveguide of the SOI structure creates electron-hole pairs when interacting with the poly-germanium region. The electron-hole pairs are collected by appropriately positioned electrodes, where the collection efficiency depends upon the separation between the electrodes and the quality of the poly-germanium material.

The generation of electron-hold pairs is directly related to the absorption of light, since every absorbed photon generates one electron-hole pair. The optical generation rate g_{OP} is given by:

$${g}_{OP} = ( \frac{α {P}_{i n} λ}{A ℏ c} ) ,$$

where A is the illuminated area of the photodiode, Pᵢₙ is the incident power, a is the absorption coefficient, h is Planck's constant, c is the velocity of light in a vacuum, and λ is the wavelength of the light signal incident on the photodetector. As an example, using a poly-germanium detector having an area A of 2 μm², if an input light signal at λ=1.55 m exhibits a power of 1 μW, then the number of electron-hole pairs generated in the volume of the detector is equal to about 8×10¹³ cm³.

Assuming all electron-hole pairs generated contribute to the photocurrent, the photocurrent can be given by the following integral:

$${I}_{p h} = qA {\int }_{- xp}^{xn + d} {g}_{OP} d x ,$$

where d is the thickness of the undoped region (which depletes), q is the electron charge, and the integration is performed over the width of the depletion region. In all cases, the integral may be reduced to:

$${I}_{p h} = \frac{q ( 1 - R ) {P}_{i n} λ}{ℏ c} ( 1 - {e}^{- α d} ) ,$$

where R is the reflection at the interface between the waveguide and the detector. A near-IR wavelength light with λ=1.55 μm, Pᵢₙ of about 1 μW and α=10³cm⁻¹ results in 1 μA of current for a detector having a length of approximately 10 μm.

Another type of photodetector useful in SOI-based structures is the Schottky barrier photodetector, which utilizes a metal-semiconductor barrier (instead of a PN junction) to convert incident light into electrical energy. In its most conventional form, a silicon-based Schottky barrier photodiode consists of a thin metallic film (such as a silicide film) disposed on a silicon layer. US Patent Publication 2005/0110108, authored by V. Patel et al. and published on May 26, 2005 describes an exemplary SOI-based Schottky barrier photodetector, where a suicide layer is disposed over a portion of the surface SOI layer of the SOI structure. An optical signal propagating laterally along the optical waveguide within the SOI layer will pass under the silicide layer, where the “tail” of the optical energy will intercept the silicide and be converted into electrical energy.

As a result of this geometry, even a relatively thin silicide layer (e.g., a few monolayers thick) will absorb a large portion of the signal over a distance of a few microns. Thus, the thickness of the absorbing silicide layer can be optimized to achieve very high internal photoemission efficiency across the Schottky barrier junction. In most cases, the Schottky barrier photodetector is operated in a reversed-biased mode so as to generate a useful electrical signal output. Operation in avalanche mode is also possible.

For a conventional, prior art normal incidence Schottky barrier photodetector, the responsivity of the detector can be optimized by performing a trade-off between the gain and absorption qualities, where both the gain and absorption are dependent on the wavelength at which the photodetector is operated. The gain represents the escape (emission) probability of a “hot” hole over the Schottky barrier. When a photon with an energy greater than the Schottky barrier height is absorbed into the silicide layer by the process of free carrier absorption, the hole gains energy and becomes “hot”. The term “hot” hole refers to a hole with a finite probability of emission over the Schottky barrier. The initial energy of a “hot” hole is proportional to the absorbed photon. Due to semi-elastic scattering events and reflections form the silicide boundaries, the “hot” hole loses energy and changes direction of travel. When the energy, position and direction of travel for a “hot” hole satisfies the condition of emission over the Schottky barrier, the hole is emitted over the barrier and produces a proportional photocurrent. If, during the process of a “hot” hole becoming a “cold” hole (i.e., a hole with zero probability of travel as a result of semi-elastic collisions and reflections), the condition of emission is not satisfied, then the “hot” hole will not be emitted over the barrier and no photocurrent will be generated.

A side view of a prior art SOI-based photodetector is shown in FIG. 1, where photodetector 1 may comprise either a PN junction-type photodetector or Schottky barrier photodetector, both types as described above. As shown, photodetector 1 is integrated with an SOI structure 2 that includes a silicon substrate 3, a buried oxide (BOX) insulating layer 4 and a relatively thin silicon surface layer 5 (hereinafter referred to as “SOI layer 5”). SOI layer 5 supports the propagation of a lightwave signal, as shown by the arrows in FIG. 1. In operation, as the lightwave signal propagates along SOI layer 5, it will couple into detector 1, creating electron-hole pairs and generating a photocurrent in the manner described above.

While SOI-based photodetectors of the type as shown in FIG. 1 represent a significant advance in the state of the art, problems arise when the input lightwave signal exhibits random, unknown polarization. When defining an incoming lightwave signal by the TE (transverse electric) and TM (transverse magnetic) polarization states, the TE mode of the signal propagates parallel to SOI layer 5, while the TM mode propagates perpendicular to SOI layer 5 (see FIG. 1). The optical propagation losses for the TE and TM polarized optical signals are different for a typical SOI waveguide. In a conventional, prior art waveguide-based detector configuration, the optical signal needs to propagate through an extended portion of the SOI waveguide, as shown in FIG. 1. As a result, the photocurrent generated in a typical waveguide-based detector exhibits strong polarization dependence.

The need remains in the art, therefore, for an SOI-based photodetector that is more efficient, in terms of generating an electrical output signal from a randomly polarized incoming optical signal.

### SUMMARY OF THE INVENTION

The need remaining in the prior art is addressed by the present invention, which relates to a photodetector arrangement for use with silicon-based opto-electronic arrangements and, more particularly, to an SOI-based photodetector integrated with an inverse nanotaper input coupler.

In accordance with the present invention, an inverse nanotaper coupling tip is used in combination with a silicon-based photodetecting device to provide more efficient opto-electronic signal conversion. In one embodiment, the inverse nanotaper coupling tip is formed within the SOI surface layer, along (or near) an endface of the SOI structure. The photodetector device is directly formed on the top surface of the inverse nanotaper itself, within close proximity of the structure endface. In another embodiment, the photodetector itself is formed to exhibit the inverse nanotaper geometry and thus provides both input signal coupling and photo-electric conversion.

The utilization of an inverse nanotaper coupling tip provides for efficient conversion of the incoming lightwave signal, where the dimensions of the tip are defined to capture the majority of the lightwave signal as it enters the SOI structure. Inasmuch as the photodetecting device is formed as an integral part of the nanotaper itself, the distance along which the signal must propagate prior to entering the photodetecting device is substantially reduced.

The arrangement of the present invention may be used as a conventional photodetector, where most (if not all) of the incoming lightwave signal is converted into an electrical output (in one case, by truncating the inverse nanotaper coupler at the termination of the tapered region). Alternatively, the inverse nanotaper photodetector may be configured as an in-line device to convert any desired fraction of the incoming lightwave signal into an electrical signal, allowing the remaining optical signal to continue to propagate along an optical waveguide contiguous with the inverse nanotaper coupling waveguide. Various types of feedback and control arrangements may desire the ability to measure/monitor only a portion of the received light signal by electrical means, and this particular arrangement of the present invention allows for this monitoring to be implemented easily and efficiently.

There are various types of silicon-based photodetecting devices that may be used in conjunction with the present invention, including a Ge-based (or SiGe-based) p-n junction detector, a metal-semiconductor junction-based Schottky barrier detector, or any other type of CMOS-compatible detector.

Other and further arrangements and embodiments of the present invention will become apparent during the course of the following discussion and by reference to the accompanying drawings.

### BRIEF DESCRIPTION OF THE DRAWINGS

Referring now to the drawings,

FIG. 1 is a side view of a prior art SOI-based photodetector arrangement;

FIG. 2 is an isometric view of an exemplary inverse nanotaper photodetector formed in accordance with the present invention, in this embodiment including an extended waveguide portion beyond the nanotaper;

FIG. 3 is a top view of the arrangement of FIG. 2;

FIG. 4 is a side view of the arrangement of FIG. 2;

FIG. 5 is an isometric view of an exemplary inverse nanotaper photodetector formed as a truncated inverse nanotaper to increase opto-electronic conversion efficiency;

FIG. 6 illustrates one embodiment of an inverse nanotaper waveguide photodetector of the present invention, utilizing a Schottky barrier photodiode arrangement;

FIG. 7 illustrates an alternative embodiment of the present invention, in this case comprising a germanium-based PN junction photodiode;

FIG. 8 is an isometric view of another arrangement of the embodiment of FIG. 7, in this case including a thin dielectric layer between the SOI layer and the germanium photodetector layer; and

FIG. 9 is an isometric view of yet another embodiment of the present invention, in this case comprising an inverse nanotaper coupler formed of photodetecting material (such as germanium or SiGe), so as to function as both an input lightwave coupler and an opto-electronic conversion element.

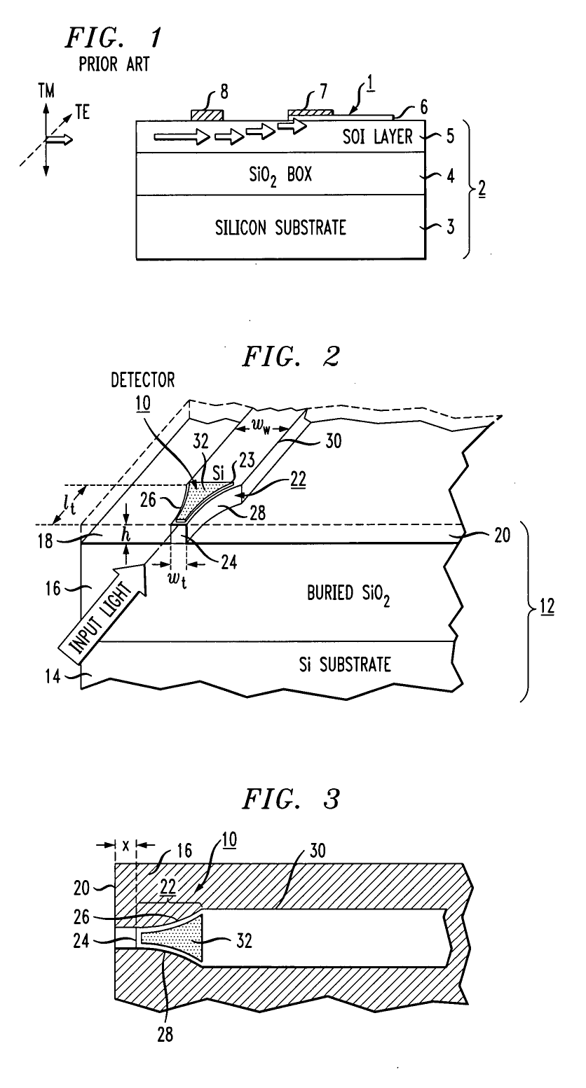

### DETAILED DESCRIPTION

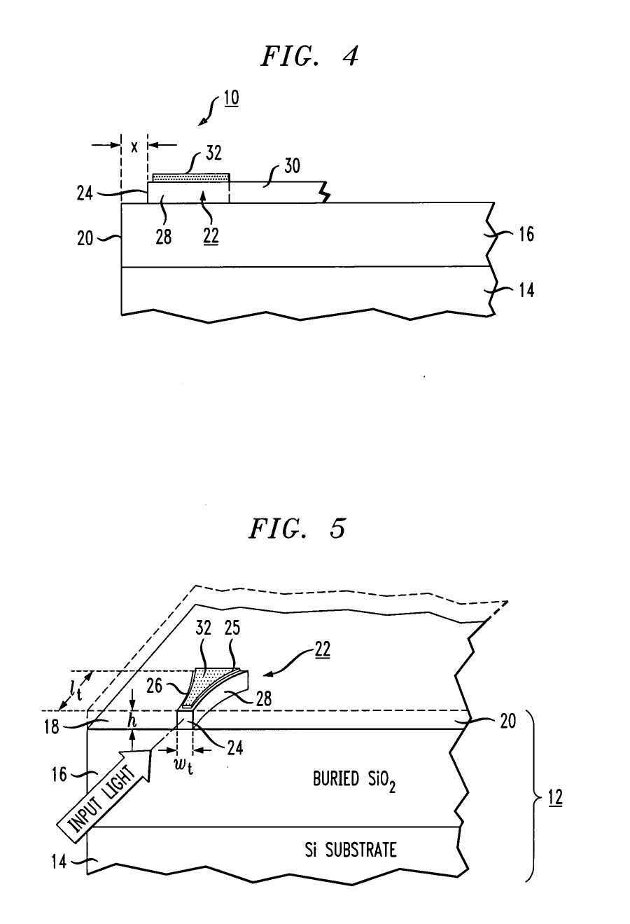

FIG. 2 is an isometric view of an exemplary inverse nanotaper photodetector 10 formed in accordance with the present invention, where FIG. 3 is a top view and FIG. 4 is a side view of the same embodiment. As shown, inverse nanotaper photodetector 10 is disposed on an SOI structure 12, where structure 12 includes a silicon substrate 14, buried oxide layer 16 and a silicon surface layer 18 (hereinafter referred to as “SOI layer 18”). The isometric view of FIG. 2 is a view along an endface 20 of SOI structure 12, with the incoming lightwave signal approaching detector 10 in the manner shown.

Detector 10 comprises an inverse nanotaper coupling waveguide 22, which is formed as an etched portion of SOI layer 18, beginning at endface 20. Waveguide 22 is formed to exhibit a predetermined height h (which may simply be the thickness of SOI layer 18, in most cases less than one micron) and a relatively narrow tip width wₜ at waveguide endface 24 (also referred to as “tip 24”). Waveguide 22 includes a pair of adiabatically-tapered sidewalls 26, 28 that extend along a length lₜ from waveguide tip 24 into a conventional rectangular waveguide portion 30, also formed within SOI layer 18. Waveguide portion 30 is shown as having a predetermined, conventional waveguide width w_{w}.

In accordance with this embodiment of the present invention, a photosensitive layer 32 is disposed over inverse nanotaper coupling waveguide 22 and utilized to collect the propagating optical signal and convert this signal into an electrical representation. As shown, layer 32 is formed to essentially follow the surface topology of the inverse nanotaper, expanding adiabatically from waveguide tip 24 toward rectangular waveguide 30. The thickness and shape of layer 32 are controlled to achieve the desired low dark current, high absorption and high speed characteristics of photodetector 10. As described above, the length lₜ and associated area of layer 32 are configured to provide for a maximum amount of optical signal to be collected and converted into an output photocurrent.

Moreover, it has been found that increased coupling efficiency between an incoming free space optical signal and inverse nanotaper coupling waveguide 22 can be achieved by recessing waveguide tip 24 by a few microns from endface 20 of SOI structure 12. The views of FIGS. 3 and 4 best illustrates this aspect, with waveguide tip 24 recessed from endface 20 a distance of x, on the order of 1-5 μm, for example.

It is further possible to utilize the inverse nanotaper photodetector of the present invention as either a conventional detector where the incoming lightwave signal is essentially completely converted into an electrical signal, or as an in-line monitoring device, where only a portion of the incoming signal is converted into an electrical representation and the remaining signal propagates along a contiguous waveguide (such as waveguide 30 of FIGS. 2-4). FIG. 5 illustrates an exemplary embodiment of the present invention where a complete conversion of the incoming optical signal into an electrical form is desired. In this case, inverse nanotaper waveguide 22 is truncated at the end of the tapered region (at length lₜ, defining a rear vertical endface 25 of waveguide 22. Thus, any optical signal remaining within waveguide 22 at endface 25 will be reflected and again pass under photodetecting layer 32.

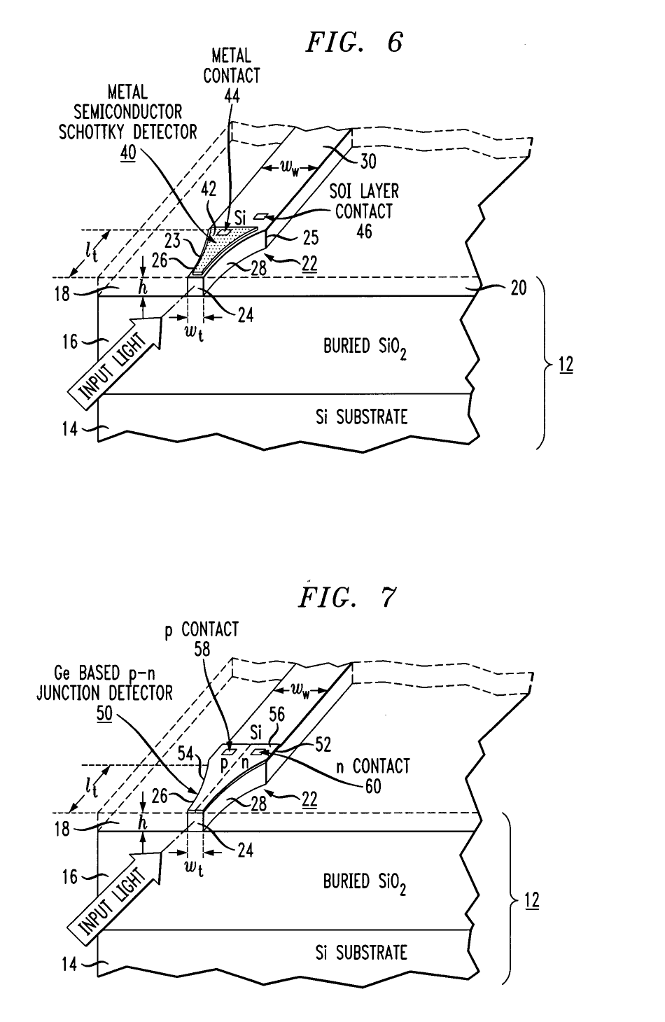

As mentioned above, the inverse nanotaper photodetector of the present invention may comprise either a Schottky barrier type of photodetector, or a germanium (including SiGe) pn junction photodiode. FIG. 6 is an isometric view of one particular embodiment of the present invention, in this case incorporating a metal-semiconductor Schottky-barrier detector 40 with inverse nanotaper coupling waveguide 22. In this particular embodiment, a layer 42 of a silicide material (such as, for example, tungsten silicide or tantalum silicide) is formed on top surface 23 of inverse nanotaper coupling waveguide 22 so as to extend nearly to waveguide tip 24.

In practice, any one of the silicides that forms an appropriate Schottky barrier for the wavelength to be detected may be used in the formation of this structure, since the ability to form a silicide on a silicon surface (that is, on the portion of SOI layer 18 forming inverse nanotaper 22) is generally understood in the planar CMOS processing industry. In a typical silicide formation process, a thin metal layer is deposited on a pre-cleaned silicon surface and then reacted with the silicon at a specific temperature(s) under controlled ambient conditions to form a silicide with specific electrical properties (e.g., resistance) and physical properties (e.g., crystal structure, grain size). The unreacted metal layer is then removed using an etch process, leaving only the silicide material on the silicon surface.

In accordance with the present invention, silicides based on cobalt, nickel, molybdenum, tantalum, tungsten and titanium are the most desired silicide layers for communication applications. The typical thickness for a silicide in the arrangement of the present invention is on the order of, for example, 5-30 Å. Silicide layer 42 may be formed as a single crystal (which is possible with some silicides), or as a polycrystalline material. For a polycrystalline silicide layer, scattering from grain boundaries plays a role (in association with the strip thickness) in determining the gain factor of detector 40. In this case, the processing conditions can be controlled, using well-known means, to optimize the grain formation in the silicide.

Referring back to FIG. 6, a first metal contact 44 is formed on silicide layer 42 and a second metal contact 46 is formed on rectangular waveguide portion 30 of SOI layer 18. As an optical signal is coupled into tip 24 of inverse nanotaper coupling waveguide 22, it will encounter the Schottky barrier created by the combination of SOI layer 18 and silicide layer 42, creating an electrical output signal between contacts 44 and 46. It is to be understood that detector 40 as shown in FIG. 6 may be formed with or without waveguide portion 30. That is, detector 40 may be terminated at endface 25 of waveguide 22 to allow for essentially all of the incoming lightwave signal to be converted to an electrical output signal. Alternatively, detector 40 may comprise an in-line arrangement, where only a portion of the incoming lightwave signal has the opportunity to be converted by silicide layer 42, the remainder of the lightwave signal thereafter propagating along waveguide portion 30.

FIG. 7 is an isometric view of an alternative embodiment of the present invention, in this case utilizing a germanium-based PN junction photodetector 50. In this case, a germanium layer 52 (which may be either single crystal or polycrystalline germanium) is disposed over inverse nanotaper coupling waveguide 22. As with the embodiment described above, the shape and placement of layer 52 is selected to achieve low dark current, high absorption and high speed. Indeed, germanium layer 52 may be grown in a self-aligned arrangement with respect to the edge of inverse nanotaper waveguide 22. Germanium layer 52 is doped with suitable materials to create the PN structure as shown, where boron may be used to create a p-doped region 54 and phosphorus used to create an n-doped region 56. A p-contact 58 is formed on portion 54 and an n-contact 60 is formed on portion 56. In this example, an incoming lightwave signal will create electron-hole pairs when interacting with the germanium region, the pairs thereafter collected by contacts 54 and 60 to create the output electrical signal. In place of utilizing pure germanium, it is to be understood that a detector utilizing SiGe may also be formed in accordance with the present invention. Although not specifically shown, the PN junction arrangement may be replaced by a PIN structure, with an “intrinsic” area formed between the P and N separate regions.

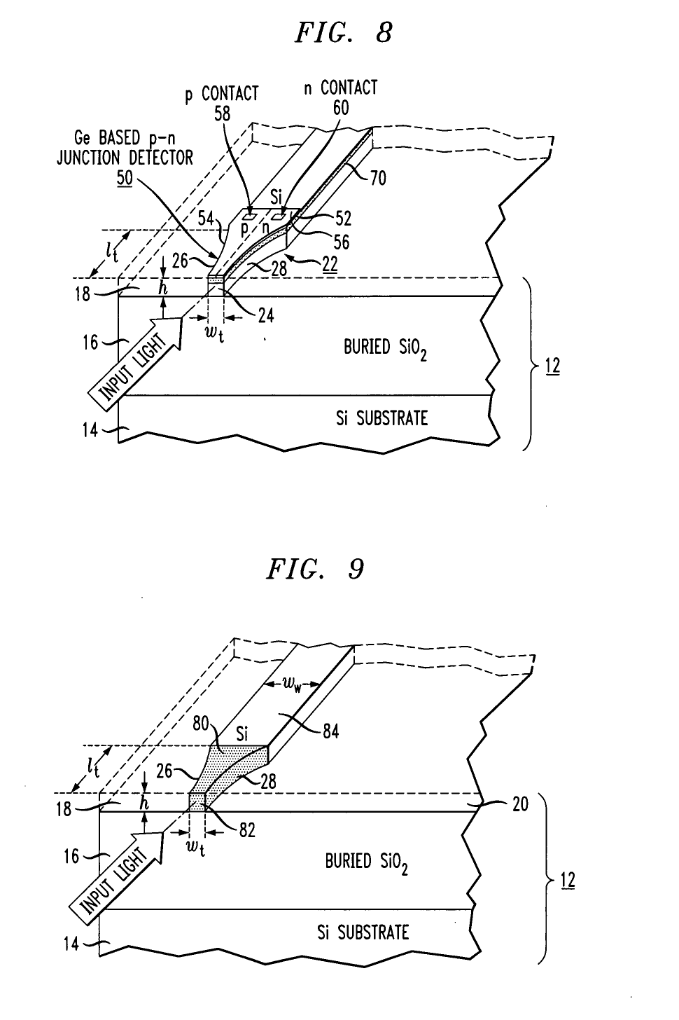

Many of the conventional processes utilized to form SOI-based opto-electronic devices include the step of forming a relatively thin dielectric layer over the top surface of the SOI layer. A germanium-based photodetector of the present invention may include this relatively thin dielectric layer, as shown in the embodiment of FIG. 8. It is clear from this view that a relatively thin dielectric layer 70 is disposed between germanium layer 52 and nanotaper waveguide 22. The presence of layer 70 allows for a simplification in the fabrication process (which would otherwise necessitate the removal of dielectric layer 70 from the photodetector area).

In another variation of this embodiment of the present invention, inverse nanotaper waveguide 22 may be replaced with a germanium (or SiGe) inverse nanotaper element 80, as shown in FIG. 9, to simultaneously provide coupling and opto-electronic conversion. In this embodiment, the incoming lightwave signal will couple into a tip portion 82 of inverse nanotaper 80 and generate a photocurrent output in the manner as described above. Again, the embodiment of FIG. 9 may comprise only inverse nanotaper 80 (in cases where it is desired to convert essentially all of the incoming lightwave signal into an electrical output signal), or may include a waveguiding region 84 (shown in phantom in FIG. 9) formed from SOI layer 18 disposed at the termination of germanium inverse nanotaper 80.

It is to be understood that the above-described embodiments of the present invention are considered to be exemplary only and should not be considered to define or limit the scope of the present invention, as defined by the claims appended hereto:

What is claimed is:

1. A photodetector arrangement based on a silicon-on-insulator (SOI) structure, the photodetector arrangement comprising:
a silicon substrate;
a buried oxide layer disposed to a predetermined thickness over the silicon substrate;
an inverse nanotaper coupling region comprising a pair of adiabatically tapering sidewalls extending from a narrowed tip first end in proximity of an endface of the SOI structure to a wider, second endface, the narrowed tip first end increasing coupling efficiency of an incoming lightwave signal; and
a photodetecting element integral with the inverse nanotaper coupling region to convert the incoming lightwave signal into an output electrical signal, wherein the location of the photodetecting element integral with said inverse nanotaper coupling region increases conversion efficiency between the incoming lightwave signal and the output electrical signal.

2. A photodetector arrangement as defined in claim 1 wherein the SOI structure further comprises a relatively thin silicon surface layer (SOI layer) disposed over the buried oxide layer, with the inverse nanotaper coupling region formed in the SOI layer.

3. A photodetector arrangement as defined in claim 1 wherein the photodetecting element comprises photodetecting material formed as the inverse nanotaper coupling region.

4. A photodetector arrangement as defined in claim 1 wherein the inverse nanotaper coupling region terminates at the wider, second endface.

5. A photodetector arrangement as defined in claim 1 wherein the arrangement further comprises an optical waveguiding region coupled to the wider, second endface of the inverse nanotaper coupling region.

6. A photodetector arrangement as defined in claim 1 wherein the photodetecting element comprises a germanium-based element.

7. A photodetector arrangement as defined in claim 6 wherein the germanium-based element comprises single crystal germanium.

8. A photodetector arrangement as defined in claim 6 wherein the germanium-based element comprises polycrystalline germanium.

9. A photodetector arrangement as defined in claim 6 wherein the germanium-based element includes a first p-doped region and a second n-doped region, with a first electrical contact coupled to the p-doped region and a second electrical contact coupled to the n-doped region.

10. A photodetector arrangement as defined in claim 9 wherein the first and second doped germanium regions are contiguous and form a PN-junction germanium-based photodetector.

11. A photodetector arrangement as defined in claim 9 wherein the first and second doped germanium regions are separated by an undoped region and form a PIN germanium-based photodetector.

12. A photodetector arrangement as defined in claim 9 wherein the first and second regions are disposed to form a vertical junction perpendicular to the SOI structure.

13. A photodetector arrangement as defined in claim 9 wherein the first and second regions are disposed to form a horizontal junction parallel to the SOI structure.

14. A photodetector arrangement as defined in claim 6 wherein the arrangement further comprises a relatively thin dielectric layer disposed between the SOI layer and the germanium-based element.

15. A photodetector arrangement as defined in claim 1 wherein the photodetecting element comprises a SiGe material.

16. A photodetector arrangement as defined in claim 2 wherein the photodetecting element comprises a Schottky barrier photodetecting structure including a silicide layer disposed over the SOI layer inverse nanotaper coupling region.

17. A photodetector arrangement as defined in claim 16 wherein the silicide is formed using a metal selected from the group consisting of: platinum, cobalt, titanium, tantalum, tungsten, nickel and molybdenum.

18. A photodetector arrangement as defined in claim 16 wherein the silicide comprises a monocrystalline silicide.

19. A photodetector arrangement as defined in claim 16 wherein the silicide comprises a polycrystalline silicide.
